(19) United States
(12) Patent Application Publication
(10) Pub. No.: US 2012/0228763 A1
(43) Pub. Date: Sep. 13, 2012

(54) SEMICONDUCTOR DEVICE AND MANUFACTURING METHOD THEREOF

(75) Inventors: Naoto AKIYAMA, Kanagawa (JP); Takashi NAKAYAMA, Kanagawa (JP); Hiroshi KISHIBE, Kanagawa (JP); Takefumi HIRAGA, Kanagawa (JP)

(73) Assignee: RENESAS ELECTRONICS CORPORATION, Kanagawa (JP)

(21) Appl. No.: 13/398,372

(22) Filed: Feb. 16, 2012

(30) Foreign Application Priority Data
Mar. 7, 2011 (JP) 2011-049262

(51) Int. Cl. H01L 23/498; H01L 21/768

(52) U.S. Cl. 257/737; 438/613; 257/E23.068; 257/E21.589

(57) ABSTRACT

A semiconductor device including a pillar formed in a highly reliable manner and a method of manufacturing the semiconductor device are disclosed. The semiconductor device includes a semiconductor chip including an internal circuit area and an I/O area disposed outside the internal circuit area, a package substrate coupled in a flip-chip manner to the semiconductor chip, and an electrically conductive pillar disposed between the semiconductor chip and the package substrate such that the electrically conductive pillar is located over two or more wirings in an uppermost wiring layer of the semiconductor chip and such that the two or more wirings are coupled together via the electrically conductive pillar.

### CROSS-REFERENCE TO RELATED APPLICATIONS

The disclosure of Japanese Patent Application No. 2011-49262 filed on Mar. 7, 2011 including the specification, drawings and abstract is incorporated herein by reference in its entirety.

### BACKGROUND

The present invention relates to a semiconductor device including a semiconductor chip coupled in a flip-chip manner to a substrate and a method of manufacturing such a semiconductor device.

In recent years, a flip-chip mounting technique has been widely used to mount semiconductor chips. The flip-chip mounting is a method of coupling a chip to a substrate such that one or more bumps (electrodes for coupling) are formed on the surface of the chip and the bumps are directly connected to the substrate. This flip-chip mounting technique may be advantageously used to achieve a reduction in size and an increase in mounting density. Each bump is coupled to a pad exposed in a flip-chip coupling surface of the semiconductor chip. The pads are coupled to a circuit area via multiple internal wiring layers.

Japanese Unexamined Patent Application Publication No. 2008-78686 discloses a semiconductor chip including bumps for use as a driver of an LCD (Liquid Crystal Display). In this technique, the bumps are coupled to pads formed on an insulating film, and wirings are formed so as to extend right below the bumps.

As the size of a semiconductor device including a semiconductor chip mounted therein is reduced, the gap between the semiconductor chip and the substrate is also reduced. However, this can cause the flip-chip coupling surface of the semiconductor chip to come into contact with the substrate. This problem is known as a belly bump problem. In particular, when the semiconductor chip used is thin, there is a possibility that the semiconductor chip is bent largely. Japanese Unexamined Patent Application Publication No. 2008-78686 discloses a technique to deal with the problem described above.

Japanese Unexamined Patent Application Publication No. 2004-104139 discloses a technique in which a supporting element is formed at a location where a belly bump can occur. More specifically, a pillar serving as the supporting element is disposed in a central area of chip (in an area inside a peripheral I/O area) to reduce the problem described above.

### SUMMARY

In some cases, the design of an LSI is changed such that a semiconductor chip originally designed to be mounted using a method other than the flip-chip mounting method is adapted for use with the flip-chip mounting. In such a case, it is necessary to dispose a pillar on the semiconductor chip originally designed to be mounted using other mounting techniques. That is, it is necessary to change the design of the semiconductor chip supposed not to use a pillar such that a pillar can be disposed on the semiconductor chip. However, it is generally difficult to make such a change in design because of a restriction on the wiring layout, and thus it is difficult to dispose a pillar for preventing the belly bump.

According to one aspect, the invention provides a semiconductor device including a semiconductor chip including an I/O area and an internal circuit area provided inside the I/O area, a substrate to which the semiconductor chip is coupled in a flip-chip manner, and an electrically conductive pillar disposed in the internal circuit area and between the semiconductor chip and the substrate such that the electrically conductive pillar is located over two or more wirings in an uppermost wiring layer of the semiconductor chip. The two or more wirings are coupled together via the electrically conductive pillar. In this semiconductor device, the electrically conductive pillar is coupled to two or more wirings. This structure ensures that a pillar is provided to a semiconductor device of a flip-chip type.

According to another aspect, the invention provides a method of manufacturing a semiconductor device, including the steps of forming an uppermost wiring layer of a semiconductor chip, forming a protective film having an opening over the uppermost wiring layer, and forming an electrically conductive pillar in an internal circuit area of the semiconductor chip such that the electrically conductive pillar couples, via the opening, two or more wirings in the uppermost wiring layer. This method ensures that a pillar is provided to a semiconductor device of a flip-chip type.

According to the aspects of the present invention, it is possible to provide a semiconductor device having a pillar and a method of manufacturing such a semiconductor device in such a manner that ensures the provision of the pillar.

### BRIEF DESCRIPTION OF THE DRAWINGS

FIG. 1 is a cross-sectional view illustrating a structure of a semiconductor device according to a first embodiment of the present invention.

FIG. 2 is a plan view illustrating the structure of the semiconductor device according to the first embodiment of the present invention.

FIG. 3 is a plan view illustrating a structure of a pillar and associated elements in the semiconductor device according to the first embodiment of the present invention.

FIG. 4 is a cross-sectional view illustrating the structure of the pillar and associated elements in the semiconductor device according to the first embodiment of the present invention.

FIG. 5 is a plan view illustrating another structure of a pillar and associated elements in the semiconductor device according to the first embodiment of the present invention.

FIG. 6 is a plan view illustrating a structure of a pillar and associated elements in a semiconductor device according to a second embodiment of the present invention.

FIG. 7 is a cross-sectional view illustrating the structure of the pillar and associated elements in the semiconductor device according to the second embodiment of the present invention.

FIG. 8 is a plan view illustrating a structure of a pillar and associated elements in a semiconductor device according to a third embodiment of the present invention.

FIG. 9 is a plan view illustrating a structure of a pillar and associated elements in a semiconductor device according to a fourth embodiment of the present invention.

FIG. 10 is a plan view illustrating a structure of a pillar and associated elements in the semiconductor device according to the fourth embodiment of the present invention.

FIGS. 11A, 11B, 11C, 11D, 11E, 11F, and 11G are cross-sectional views illustrating processing steps of manufacturing a semiconductor device.

### DETAILED DESCRIPTION OF THE PREFERRED EMBODIMENTS

### First Embodiment

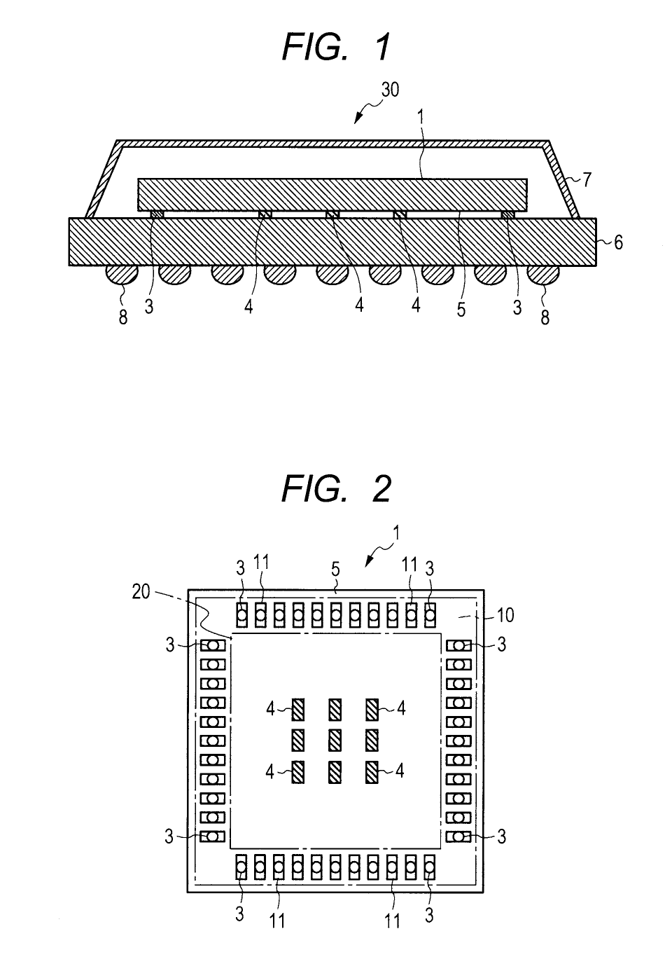

An embodiment of the present invention is described below with reference to the accompanying drawings. FIG. 1 is a cross-sectional view illustrating a structure of a semiconductor device according to a first embodiment of the present invention. As shown in FIG. 1, a semiconductor device 30 according to the present embodiment is of a flip-chip type. The semiconductor device 30 includes a semiconductor chip 1, pillars 3, pillars 4, a package substrate 6, a casing 7, and metal balls 8. Note that the casing 7 may be a mold.

The semiconductor chip 1 is mounted in a flip-chip manner over the package substrate 6 such that the semiconductor chip 1 and the package substrate 6 face each other. For convenience, of surfaces of the semiconductor chip 1, a surface facing the package substrate 6 is referred to as a flip-chip coupling surface 5. The casing 7 is attached to the package substrate 6. The semiconductor chip 1 is located in a space formed between the casing 7 and the package substrate 6.

The pillars 3 are disposed between the semiconductor chip 1 and the package substrate 6 such that the semiconductor chip 1 is electrically coupled to the package substrate 6 via the pillars 3. More specifically, the pillars 3 are coupled to wirings or the like formed over the package substrate 6. The metal balls 8 are disposed on a surface of the package substrate 6 opposite to the semiconductor chip 1. The metal balls 8 may be, for example, solder balls. The metal balls 8 may be arranged in the form of an array to achieve a BGA (Ball Grid Array). The package substrate 6 has wirings for coupling pillars 3 to corresponding metal balls 8. The package substrate 6 may be coupled to another wiring substrate or the like via the metal balls 8. The pillars 4 are disposed between the semiconductor chip 1 and the package substrate 6. The provision of the pillars 4 prevents semiconductor chip 1 from having a belly bump. The structure of the packaged semiconductor device 30 has been described above. Note that in this structure, the pillar 4 is in contact with the package substrate 6.

FIG. 2 illustrates a structure of the flip-chip coupling surface 5 of the semiconductor chip 1. As shown in FIG. 2, the semiconductor chip 1 has an I/O area 10 and an internal circuit area 20. In the internal circuit area 20, an internal circuit or the like, which is a main part of the semiconductor chip 1, is formed. The internal circuit (not shown) formed in the internal circuit area 20 allows the semiconductor chip 1 to function in a particular manner. The I/O area 10 is formed around the internal circuit area 20. In other words, the rectangular-shaped internal circuit area 20 is disposed inside the frame-shaped I/O area 10. In the I/O area 10, an I/O buffer circuit (not shown) and/or the like is formed.

Multiple input/output terminals 11 are formed in the I/O area 10. The input/output terminals 11 are pads for inputting or outputting a power supply voltage, signals, or the like. The input/output terminals 11 may be formed, for example, using an uppermost wiring layer as described later. Input signals to the internal circuit area 20 and output signals from the internal circuit area 20 are input or output via the input/output terminals 11. Furthermore, a power supply voltage, a ground voltage, or the like are also input to the internal circuit area 20 via input/output terminals 11. The input/output terminals 11 are arranged along a periphery of the semiconductor chip 1. The pillars 3 are formed over corresponding input/output terminals 11. Note that each input/output terminal 11 is in contact with a corresponding one of pillars 3 such that they are electrically coupled.

Furthermore, the pillars 4 are formed in the internal circuit area 20. The pillars 4 are pillar-shaped supporting elements formed of a conductive material such as Cu (copper) or the like. Although in the example shown in FIG. 2, the pillars 4 are arranged in a 3 x 3 array, the number of pillars 4 and the manner of arranging them are not limited to those employed in this example.

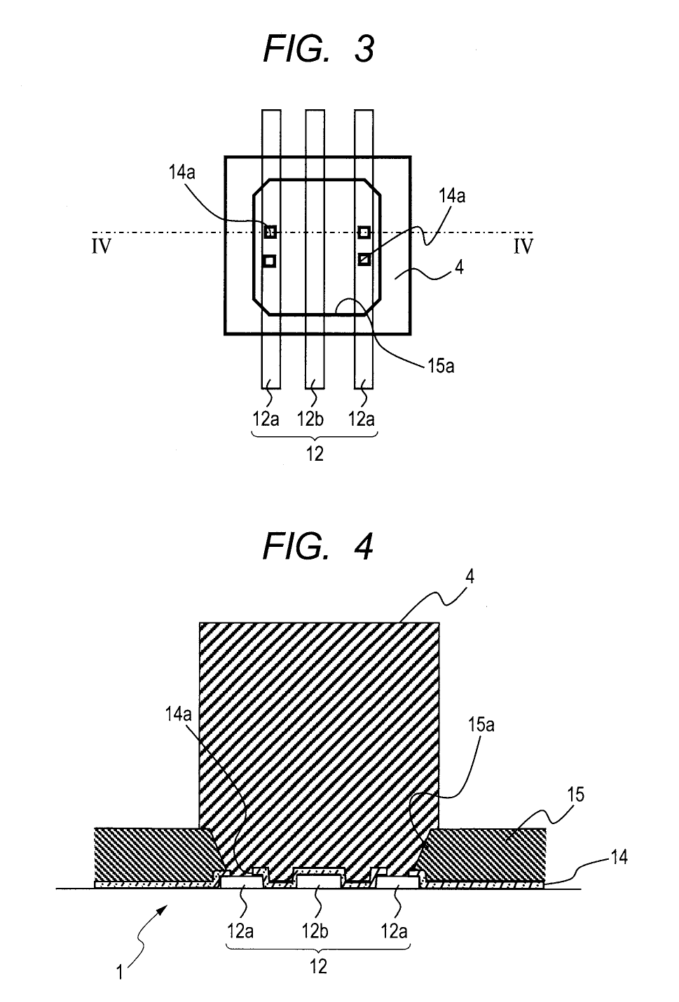

Next, referring to FIG. 3 and FIG. 4, a structure and a manner of coupling the pillars 4 are described below. FIG. 3 is a plan view illustrating the structure of a pillar 4 and associated elements in the flip-chip coupling surface 5. FIG. 4 is a cross-sectional view taken along line IV-IV of FIG. 3. Note that FIG. 3 and FIG. 4 show one of the pillars 4 in an enlarged manner to illustrate a manner of coupling the pillar 4. Note that the structure illustrated in the cross-sectional view of FIG. 4 is upside-down compared with the illustration in FIG. 1. Thus in FIG. 4, the upper part of the shown structure is located on the side of the package substrate 6. Furthermore, in FIG. 4, the structure of a part of the semiconductor chip 1 below the uppermost wiring layer 12 is not shown. For example, wiring layers, interlayer insulating films, transistors, and other elements located below the uppermost wiring layer 12 are not shown in FIG. 4.

The semiconductor chip 1 has the uppermost wiring layer 12. The semiconductor chip 1 has multiple wiring layers. Of these wiring layers, one located in the upper most layer is referred to as the uppermost wiring layer 12. In the I/O area 10, the uppermost wiring layer 12 is patterned to provide the input/output terminals 11. The uppermost wiring layer 12 may be formed by a metal film such as an aluminum film, and the wirings in the uppermost wiring layer 12 may be formed by patterning the metal film. The uppermost wiring layer 12 includes one or more ground wirings 12a and one or more power supply wirings 12b. A ground voltage provided from one of the input/output terminals 11 is supplied to the ground wiring 12a. A power supply voltage provided from one of the input/output terminals 11 is supplied to the power supply wiring 12b. As shown in FIG. 3, the ground wiring 12a and the power supply wiring 12b have the same width and extend in parallel. In the example shown in FIG. 3, two ground wirings 12a and one power supply wiring 12b are formed such that they all extend in a vertical direction in the figure and such that one power supply wiring 12b is located between the two ground wirings 12a. The ground wirings 12a and the power supply wiring 12b are coupled to protection devices such as diodes in, for example, the I/O area 10.

The pillars 4 are disposed above the uppermost wiring layer 12. In the example shown in FIG. 3, the pillar 4 has a width greater than the width of each wiring formed in the uppermost wiring layer 12. More specifically, in this example, the pillar 4 is formed across three wirings, i.e., two ground wirings 12a and one power supply wiring 12b. The pillar 4 has a square shape in plan view. In the shape of the pillar 4 in plan view, corners of the square may be rounded.

A first protective film 14 is formed in a layer above the uppermost wiring layer 12, and a second protective film 15 is formed in a layer above the first protective film 14. The first protective film 14 and the second protective film 15 are made of an electrically insulating material. The pillars 4 are formed at positions above the second protective film 15. In an area right below the pillar 4, the first protective film 14 has an opening 14a, and the second protective film 15 has an opening 15a. The first protective film 14 covers the power supply wiring 12b. The opening 14a is formed so as to reach the ground wiring 12a. In plan view, the opening 14a is formed so as not to extend outward from the ground wiring 12a. The opening 15a is formed so as to reach the surface of the first protective film 14. In plan view, the pillar 4 has a greater size than the size of the opening 15a such that the pillar 4 covers the opening 15a. Thus, in areas where the opening 14s overlap the opening 15a, the pillar 4 reaches the ground wiring 12a. The pillar 4 is coupled to the two ground wirings 12a via the openings 14a and the opening 15a. As a result, the two ground wirings 12a are electrically coupled via the pillar 4.

The power supply wiring 12b is disposed between the two ground wirings 12a. The openings 14a are located above the two respective ground wirings 12a such that each ground wiring 12a has two openings 14a. Thus in the example shown in FIG. 3, four openings 14a are formed in the first protective film 14. The opening 15a is formed so as to cover the four openings 14a. The pillar 4 overlaps the four openings 14a. The two ground wirings 12a are electrically coupled to the pillar 4 via the four openings 14a. In other words, the two ground wirings 12a are electrically coupled via the pillar 4. This makes it possible to increase the stability and reliability of the ground voltage.

In plan view, the pillar 4 has a size of, for example, 30 to 50 μm square. In the uppermost wiring layer 12, the width of wirings is 3 to 20 μm, which is smaller than the size of the pillar 4. The size of each opening 14a is 1 to 3 μm square, which is smaller than the width of wirings in the uppermost wiring layer 12. Thus, each opening 14a is formed so as not to extend outward from the corresponding ground wiring 12a. The width of wirings in the uppermost wiring layer 12 may be set to equal to the width of wires in the internal circuit area 20. In this structure, the pillars 4 can be disposed without changing the pitch of the wirings in the uppermost wiring layer 12. In the present embodiment, multiple ground wirings 12a extend through a region immediately below the pillar 4 and thus ground wirings 12a are coupled together via the pillar 4 disposed above the openings 14a. This makes it possible to increase the stability and reliability of the ground voltage in a central area of the internal circuit area 20. Each wiring is generally coupled to a protection device. If so, it is not necessary to couple the wirings to additional protection devices.

The data ratio of the uppermost wiring layer 12 is generally 50 to 90%. The data ratio refers to a ratio, in plan view, of an area occupied by the uppermost wiring layer 12 to the total area of the semiconductor chip 1. In a case where the data ratio is greater than 50%, it is difficult to change a layout of wirings. More specifically, it is difficult to increase the width of wirings to make it possible to dispose the pillar 4. However, the above-described structure according to the present embodiment makes it possible to dispose the pillars 4 without changing the layout of wirings or the width of wirings. Thus, it becomes possible for the semiconductor chip 1 to be mounted using the flip-chip mounting method even when the semiconductor chip 1 is originally designed to be mounted using a method other than the flip-chip mounting method. Note that the pillar 4 for preventing the belly bump can be provide without changing the design of the uppermost wiring layer 12. In the structure described above, the electrically conductive pillar 4 is coupled to the uppermost wiring layer 12. This leads to an increase in adhesion strength between the semiconductor chip 1 and the pillar 4 compared with a structure in which the pillar 4 is not coupled to the uppermost wiring layer 12. Furthermore, the provision of multiple openings 14a to each ground wiring 12a results in a further improvement in adhesion strength of the pillar 4.

The above-described structure according to the present embodiment ensures that the pillar 4 for preventing the belly bump is provided to the semiconductor chip 1 of the flip-chip type. Because it is not necessary to make any change in the wiring layout of the uppermost wiring layer or only a slight change is sufficient even if necessary, it is possible to provide the pillar 4 to the semiconductor chip in the middle of or after the completion of the design thereof. For example, for a semiconductor chip originally designed to be wire-bonded to produce a semiconductor device, it is possible to modify the semiconductor chip such that it can be coupled using the flip-chip technique. Furthermore, it is possible to increase the stability and the reliability of the ground voltage.

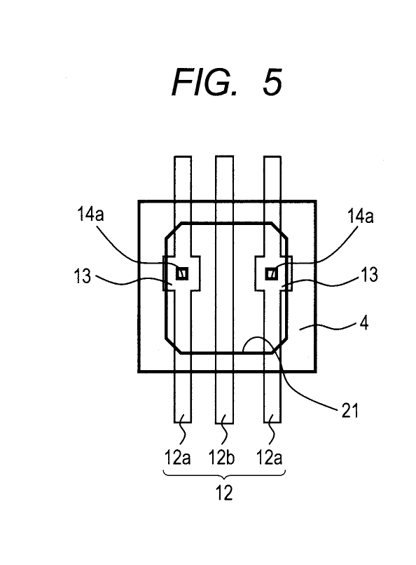

In the example described above, the ground wirings 12a all have a constant width, but one or more ground wirings 12a may include a part with a greater width, as shown in FIG. 5. In the example shown in FIG. 5, each ground wiring 12a has a part serving as a seat 13 with a greater width than the width of the main part of the ground wiring 12a. The seat 13 of each ground wiring 12a is formed such that it is not in contact with the adjacent power supply wiring 12b. In other words, the width of the seat 13 is smaller than the space between the main part of the ground wiring 12a and the main part of the power supply wiring 12b. The opening 14a is formed so as to be located right above the seat 13 of the ground wiring 12a. The size of the opening 14a is set to be smaller than the size of the seat 13. This structure can be realized by performing a slight modification on the layout of wirings in the uppermost wiring layer 12. In this structure, it is possible to expand the size of the opening 14a up to a limit not exceeding the width of the seat 13. This ensures that the pillars 4 are disposed in a proper and reliable manner.

In the example described above, two or more ground wirings 12a are coupled together via one pillar 4. Alternatively, multiple power supply wirings 12b may be coupled together via a pillar 4. Of course, of the pillars 4, some pillars 4 may be used to couple multiple ground wirings 12a together, and some other pillars 4 may be used to couple multiple power supply wirings 12b together such that the respective pillars 4 serve as parts of the power supply line or the ground line. This makes it possible for the power supply wirings 12b and the ground wirings 12a to provide the power supply voltage or the ground voltage with improved reliability and stability. Of course, where there are multiple power supply lines, one or more pillars 4 may be disposed for each power supply line such that power supply lines at the same potential are coupled together via the pillars.

### Second Embodiment

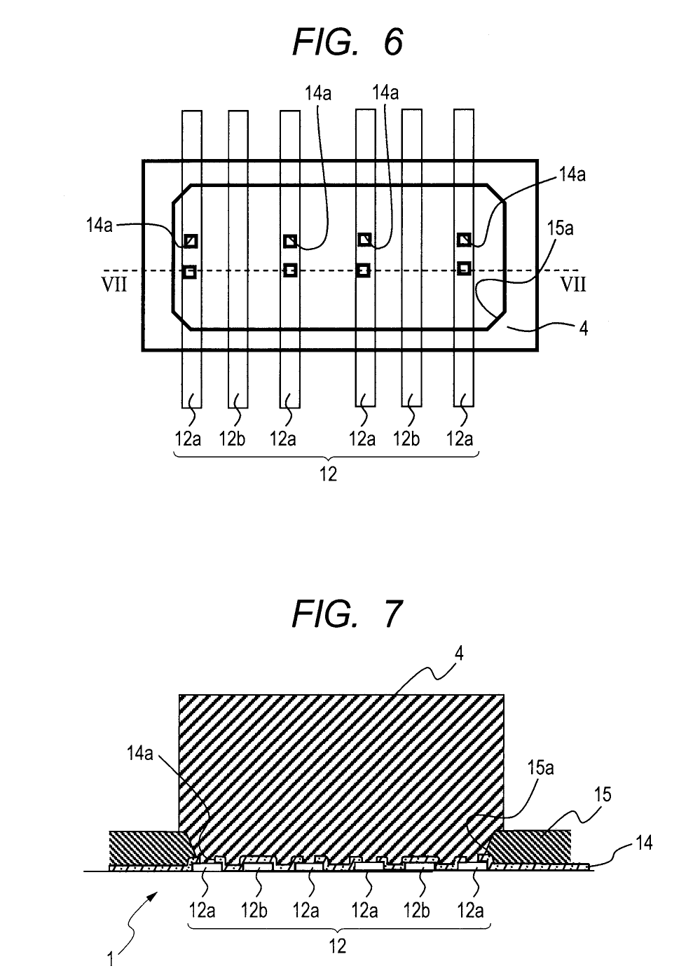

In a second embodiment described below, pillars are different in shape in plan view from those according to the first embodiment. In terms of other basic structures, the semiconductor device 30 according to the present embodiment is similar to that according to the first embodiment, and thus a further description thereof is omitted. Referring to FIG. 6 and FIG. 7, the shape of pillars used in the semiconductor device according to the present embodiment is described below. FIG. 6 is a plan view illustrating a structure of a pillar 4 and associated elements located in the vicinity of the pillar 4 in a flip-chip coupling surface 5. FIG. 7 is a cross-sectional view taken along ling VII-VII of FIG. 6.

As shown in FIG. 6, the pillar 4 has a rectangular shape in plan view. That is, the pillar 4 is formed so as to have a large width. Of course, the pillar 4 may be formed to have a rectangular shape with rounded corners, i.e., the pillar 4 may have an elliptic shape. The longitudinal direction of the pillar 4 is perpendicular to the wiring direction in the uppermost wiring layer 12, and the lateral direction thereof is parallel to the wiring direction. In the example shown in FIG. 6 and FIG. 7, the pillar 4 is formed across four ground wirings 12a and two power supply wirings 12b. That is, the pillar 4 is formed such that the pillar 4 overlaps, in plan view, six wirings in the uppermost wiring layer 12. In the example shown in FIG. 6, a ground wiring 12a, a power supply wiring 12b, another ground wiring 12a, still another ground wiring 12a, another power supply wiring 12b, and still another ground wiring 12a are arranged in this order from left to right. These six lines have the same width and extend in parallel.

The first protective film 14 has openings 14a formed right above the respective four ground wirings 12a. In the example shown in FIG. 6, two openings 14a are formed for each ground wiring 12a, and thus a total of eight openings 14a are formed. The second protective film 15 has an opening 15a formed such that the opening 15a overlaps, in plan view, the six wirings. The second pillar 4 is formed so as to have a great width that covers the opening 15a. The ground wirings 12a are coupled to the pillar 4 via the openings 14a and the opening 15a. Thus, the four ground wirings 12a are coupled together via the pillar 4. This makes it possible for the ground wirings 12a to provide the ground voltage in a more stable and reliable manner.

By forming the pillar 4 such that the longitudinal direction of the pillar 4 is perpendicular to the wiring direction, it becomes possible to couple a greater number of ground wirings 12a together. More specifically, in the present example, the pillar 4 is formed such that the pillar 4 overlaps, in plan view, the four ground wirings 12a whereby the ground wirings 12a are coupled together via the pillar 4. This makes it possible for the ground wirings 12a to provide the ground voltage in a more stable and reliable manner. This structure is useful in particular when it is difficult to increase the perimeter of the pillar 4 because of the restriction on the design or production process. Furthermore, this structure allows the ground wirings 12a to be coupled to the pillar 4 via a large number of openings 14a, and thus it is possible to improve the adhesion strength between the pillar 4 and the semiconductor chip 1. Note that the longitudinal direction of the pillar 4 may not be exactly perpendicular to the wiring direction, as long as the longitudinal direction of the pillar 4 crosses the wiring direction. Also note that there is no particular restriction on the number of ground wirings 12a coupled to the pillar 4.

### Third Embodiment

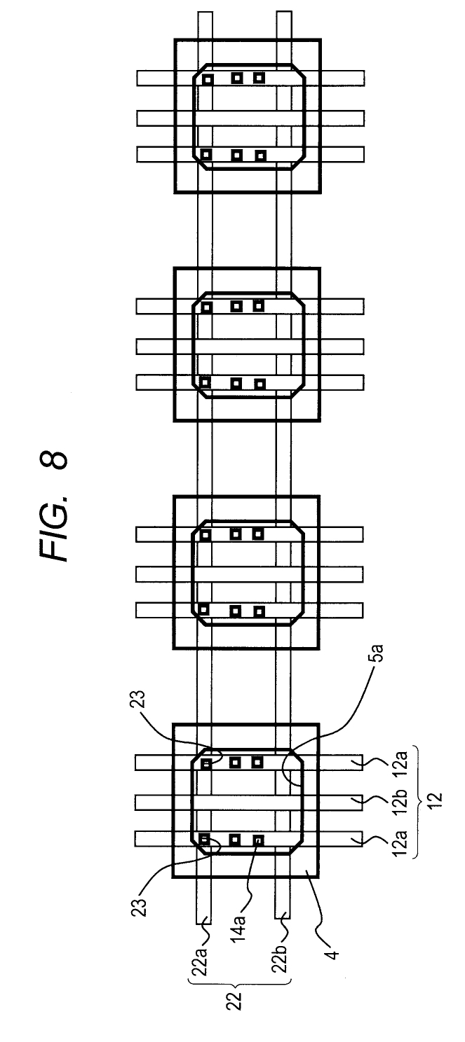

Referring to FIG. 8, a semiconductor device 30 according to a third embodiment of the present invention is described below. FIG. 8 is a plan view illustrating a structure including pillars 4 and associated elements in a flip-chip coupling surface 5. The semiconductor device 30 is configured in a similar manner to that according to first embodiment, and thus a further description thereof is omitted. As shown in FIG. 8, a lower wiring layer 22 is disposed below an uppermost wiring layer 12. For example, in a case where the semiconductor chip 1 includes a total of seven wiring layers, the uppermost wiring layer 12 is a seventh layer, and the lower wiring layer 22 may be a fourth layer. Wirings in the lower wiring layer 22 extend in a direction perpendicular to a direction of wirings in the uppermost wiring layer 12. That is, the wirings in the lower wiring layer 22 cross, via an interlayer insulating layer, the wirings in the uppermost wiring layer 12. More specifically, in the example shown in FIG. 8, the wirings in the uppermost wiring layer 12 extend in a vertical direction in the figure, while the wirings in the lower wiring layer 22 extend in a horizontal direction in the figure. The lower-layer ground wiring 22a and the lower-layer power supply wiring 22b in the lower wiring layer 22 extend in parallel.

In the present embodiment, multiple pillars 4 are arranged in a direction perpendicular to the direction of the wirings in the uppermost wiring layer 12. In the example shown in FIG. 8, four pillars 4 are arranged in a horizontal direction in the figure. These four pillars 4 are similar in structure. More specifically, as in the first embodiment, two ground wirings 12a are coupled together via each pillar 4.

Furthermore, via the ground wirings 12a, each pillar 4 is coupled to the lower-layer ground wiring 22a. In this specific example, right below each pillar 4, the lower-layer ground wiring 22a is coupled to the ground wirings 12a. At an intersection between the lower-layer ground wiring 22a and each ground wiring 12a, a via-hole 23 is formed in the interlayer insulating film. In many cases, the wirings in the lower wiring layer 22 are smaller in width and higher in resistance than the wirings in the uppermost wiring layer 12 are. However, the above-described structure according to the present embodiment makes it possible for the lower wiring layer 22 to provide a ground voltage with improved stability and reliability. Furthermore, the provision of the via-hole 23 in the interlayer insulating film at the intersection between the lower-layer ground wiring 22a and the lower-layer power supply wiring 22b makes it unnecessary to change the layout of wirings. Of course, the lower-layer ground wiring 22a may be coupled to the ground wiring 12a at a location other than the location right below the pillar 4. In most cases, the ground wiring 12a is coupled, at some location in an LSI, to the lower-layer ground wiring 22a such that a power supply network is formed. In this case, only by coupling the pillar 4 to the ground wiring 12a, it becomes possible for the ground wiring in the power supply network to provide a highly stable and reliable ground voltage even if the ground wiring 12a is not coupled to the lower-layer ground wiring 22a via the via-hole 23 right below the pillar 4.

### Fourth Embodiment

In a fourth embodiment described below, a semiconductor chip 1 has pillars 4 that are different in shape in plan view. That is, of the pillars 4 shown in FIG. 2, at least one pillar has a different shape in plan view from the shape of the other pillars. Other elements of the semiconductor device 30 are similar manner to those according to first embodiment, and thus a further description thereof is omitted. Referring to FIG. 9 and FIG. 10, the semiconductor device 30 according to the present embodiment of the invention is described below. FIG. 9 is a plan view illustrating a structure of one of the pillars 4 and associated elements, and FIG. 10 is a plan view illustrating a structure of another one of the pillars 4 and associated elements.

In the present embodiment, the semiconductor device 30 includes pillars 4 having different shapes. For example, the pillar 4 shown in FIG. 9 has a square shape similar to that according to the first embodiment, and the pillar 4 shown in FIG. 10 has a rectangular shape similar to that according to the second embodiment. As can be seen, the pillar 4 shown in FIG. 10 is formed so as to have a large width. Of course, corners of each pillar 4 may be rounded in plan view.

In the present embodiment, when seen in plan view, the two pillars 4 are different in perimeter and area size to adjust the height of the pillars 4 such that the two pillars 4 disposed at different locations in the semiconductor chip 1 are substantially equal in height. The pillars 4 are generally produced by a plating process, and thus the height thereof can vary depending on whether the pillars 4 are located in a peripheral area or a central area of the semiconductor chip 1 or depending on the cross-sectional area size (the manner of supplying an electric current in the plating process). For example, when the pillar 4 disposed in the central region of the internal circuit area 20 has the same cross-sectional area size as that of the pillar 4 disposed close to the I/O area 10, there may be a difference in height between these pillars 4. By property setting the perimeter or the area size depending on the location in the semiconductor chip 1, it is possible to achieve the same height for multiple pillars 4.

That is, it is possible to adjust the height of the pillars 4 by properly changing the perimeter or the area of the pillars 4 depending on their location in the semiconductor chip 1. Thus it is possible to minimize the difference in height among pillars 4 formed at various locations in the semiconductor chip 1. This makes it possible to dispose pillars 4 at various locations, such as locations close to the I/O area 10, locations in the central region of the internal circuit area 20, etc., in the semiconductor chip 1. In the central region of the internal circuit area 20, because of a large distance from the I/O area 10 to which the external power supply is coupled, the ground voltage may become unstable or unreliable. In such a structure, if pillars are disposed in the central region of the internal circuit area 20, it becomes possible for the ground wiring 12a to provide the ground voltage with improved stability and reliability. Method of manufacturing semiconductor device

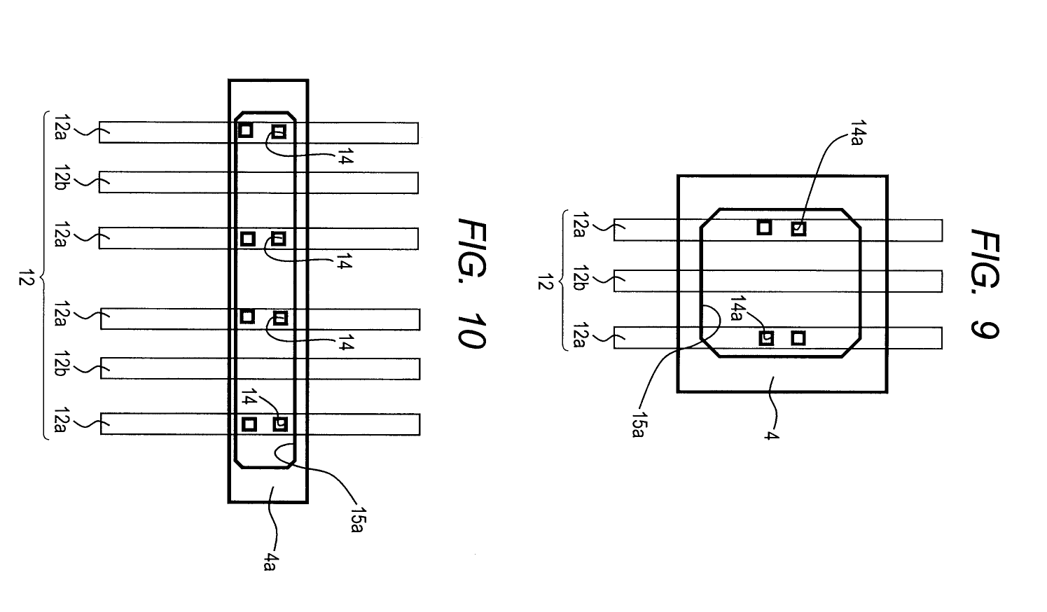

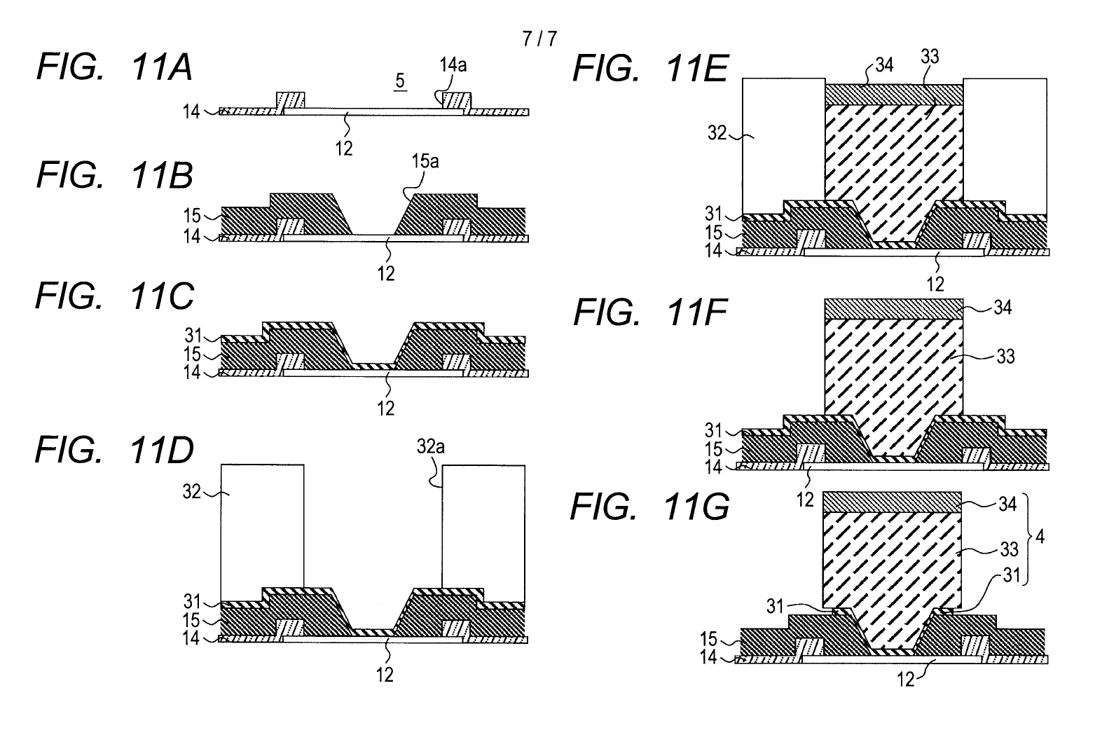

Referring to FIGS. 11A to 11G, a method of manufacturing the semiconductor device 30 according to an embodiment of the invention is described below. FIGS. 11A to 11G are cross-sectional views illustrating a method of manufacturing the semiconductor device 30. These figures illustrate a process from a step of producing an uppermost wiring layer 12 to a step of forming a pillar 4. The other steps may be performed according to a known method, and a further description thereof is mitted. For example, the internal circuit in the internal circuit area 20, various semiconductor devices in the I/O buffer in the internal circuit area 20, wirings, interlayer insulating films, and the like may be produced using known methods, and thus, a further description thereof is omitted.

First, as shown in FIG. 11A, the uppermost wiring layer 12 and a first protective film 14 are formed. More specifically, for example, a metal film such as an aluminum film or the like is formed, and the metal film is patterned by etching it using a common photolithography process. The first protective film 14 is then formed over the uppermost wiring layer 12. As for the first protective film 14, for example, an inorganic insulating film or the like may be used. The first protective film 14 is then patterned to form an opening 14a. Thereafter, as shown in FIG. 11B, a second protective film 15 is formed. More specifically, the second protective film 15 is formed over the first protective film 14 including the opening 14a. The second protective film 15 is then patterned to form an opening 15a in the second protective film 15. As for the second protective film 15, for example, an organic insulating film such as a polyimide film may be used.

Thereafter, for preparation for a plating process, a seed metal 31 is formed over the second protective film 15. The seed metal 31 is formed over the substantially entire surface of the second protective film 15. As a result, a structure such as that shown in FIG. 11C is obtained. Thereafter, a resist 32 is formed over the seed metal 31 as shown in FIG. 11D. More specifically, a photosensitive resin layer is coated, exposed, and developed to obtain the resist pattern 32. The resist 32 has an opening 32a formed at a location where the pillar 4 is to be formed.

Thereafter, plating is performed to obtain a structure shown in FIG. 11E. More specifically, Cu—SnAg plating may be performed such that a Cu layer 33 is formed over the seed metal 31 in the opening 32a of the resist 32, and a SnAg layer 34 is formed over the Cu layer 33. After the plating process, the resist 32 is removed. As a result, a structure shown in FIG. 11F is obtained. The seed metal 31 is then etched to obtain a structure shown in FIG. 11G. More specifically, a part of the seed metal 31 exposed without being covered with the Cu layer 33 and the SnAg layer 34, i.e., the part which was covered with the resist 32 that has already been removed, is removed. Thus, the pillar 4 in contact with a wiring in the uppermost wiring layer 12 is obtained. The height of the pillar 4 may be, for example, a few ten w. The shape of the pillar 4 is determined by the shape of the opening 32a of the resist 32. This makes it possible to achieve high precision in producing the pillar 4 enhancing the reliability of wiring lines.

Note that the present invention is not limited to specific embodiments described above, but many modifications are possible without departing from the spirit and scope of the present invention. Also note that two or more of the first to fourth embodiments described above may be combined.

1-11. (canceled)

12. A semiconductor device comprising:
a semiconductor chip including an I/O area and an internal circuit area provided inside the I/O area;
a substrate to which the semiconductor chip is coupled in a flip-chip manner; and
an electrically conductive pillar disposed in the internal circuit area and between the semiconductor chip and the substrate such that the electrically conductive pillar is located over two or more wirings in an uppermost wiring layer of the semiconductor chip whereby the two or more wirings are coupled together via the electrically conductive pillar.

13. The semiconductor device according to claim 12, further comprising a lower wiring layer disposed in a layer below the uppermost wiring layer and including a wiring that extends in a direction crossing the two or more wirings in the uppermost wiring layer and that is equal in potential to one of wirings in the uppermost wiring layer,
wherein a plurality of electrically conductive pillars are arranged along the direction of the wiring in the lower wiring layer.

14. The semiconductor device according to claim 12, wherein at least one of the electrically conductive pillars has a different shape in plan view from a shape of the other electrically conductive pillars, and the electrically conductive pillar having the different shape in plan view has substantially the same height as the height of the other electrically conductive pillars.

15. The semiconductor device according to claim 12, wherein when seen in plan view, electrically conductive pillars have a longitudinal direction in parallel to a direction crossing the two or more wirings.

16. The semiconductor device according to claim 12, further comprising a protective film formed between the uppermost wiring layer and the electrically conductive pillar,
wherein the protective film has an opening smaller than a width of a wiring in the uppermost wiring layer, and
wherein the wiring in the uppermost wiring layer is coupled to the electrically conductive pillar via the opening.

17. The semiconductor device according to claim 12, wherein the two or more wirings are power supply wirings or group wirings.

18. A method of manufacturing a semiconductor device including a semiconductor chip coupled in a flip-chip manner to a substrate, comprising:
forming an uppermost wiring layer of the semiconductor chip; and
forming an electrically conductive pillar in an internal circuit area of the semiconductor chip such that the electrically conductive pillar couples two or more wirings in the uppermost wiring layer.

19. The method of manufacturing the semiconductor device according to claim 18, further comprising:
forming a lower wiring layer in a layer below the uppermost wiring layer such that the lower wiring layer includes a wiring extending in a direction crossing the two or more wirings in the uppermost wiring layer,
wherein a plurality of electrically conductive pillars are arranged along the direction of the wiring in the lower wiring layer.

20. The method of manufacturing the semiconductor device according to claim 18, wherein a plurality of electrically conductive pillars are formed such that a perimeter and an area size are different among the electrically conductive pillars so as to achieve a substantially equal height for the electrically conductive pillars.

21. The semiconductor device according to claim 18, wherein, when seen in plan view, electrically conductive pillars have a longitudinal direction in parallel to a direction crossing the two or more wirings.

22. The semiconductor device according to claim 18, further comprising:
forming a protective film having an opening over the uppermost wiring layer,
wherein the two more wirings in the uppermost wiring layer are coupled to the electrically conductive pillar via the opening.

23. The semiconductor device according to claim 13, wherein at least one of the electrically conductive pillars has a different shape in plan view from a shape of the other electrically conductive pillars, and the electrically conductive pillar having the different shape in plan view has substantially the same height as the height of the other electrically conductive pillars.

24. The semiconductor device according to claim 13, wherein when seen in plan view, electrically conductive pillars have a longitudinal direction in parallel to a direction crossing the two or more wirings.

25. The semiconductor device according to claim 14, wherein when seen in plan view, electrically conductive pillars have a longitudinal direction in parallel to a direction crossing the two or more wirings.

26. The semiconductor device according to claim 13, further comprising a protective film formed between the uppermost wiring layer and the electrically conductive pillar,
wherein the protective film has an opening smaller than a width of a wiring in the uppermost wiring layer, and
wherein the wiring in the uppermost wiring layer is coupled to the electrically conductive pillar via the opening.

27. The semiconductor device according to claim 14, further comprising a protective film formed between the uppermost wiring layer and the electrically conductive pillar,
wherein the protective film has an opening smaller than a width of a wiring in the uppermost wiring layer, and
wherein the wiring in the uppermost wiring layer is coupled to the electrically conductive pillar via the opening.

28. The semiconductor device according to claim 15, further comprising a protective film formed between the uppermost wiring layer and the electrically conductive pillar,
wherein the protective film has an opening smaller than a width of a wiring in the uppermost wiring layer, and
wherein the wiring in the uppermost wiring layer is coupled to the electrically conductive pillar via the opening.

29. The semiconductor device according to claim 13, wherein the two or more wirings are power supply wirings or group wirings.

30. The semiconductor device according to claim 14, wherein the two or more wirings are power supply wirings or group wirings.

31. The semiconductor device according to claim 15, wherein the two or more wirings are power supply wirings or group wirings.
